(19) United States
(12) Patent Application Publication
(10) Pub. No.: US 2013/0252417 A1
(43) Pub. Date: Sep. 26, 2013

(54) THIN FILM FORMING METHOD

(71) Applicants: Tadahiro ISHIZAKA, Nirasaki City (JP); Jonathan Rullan, Albany, NY (US); Osamu Yokoyama, Nirasaki City (JP); Atsushi Gomi, Nirasaki City (JP); Chiaki Yasumuro, Nirasaki City (JP); Takara Kato, Nirasaki City (JP); Tatsuo Hatano, Nirasaki City (JP); Hiroaki Kawasaki, Nirasaki City (JP)

(72) Inventors: Tadahiro ISHIZAKA, Nirasaki City (JP); Jonathan Rullan, Albany, NY (US); Osamu Yokoyama, Nirasaki City (JP); Atsushi Gomi, Nirasaki City (JP); Chiaki Yasumuro, Nirasaki City (JP); Takara Kato, Nirasaki City (JP); Tatsuo Hatano, Nirasaki City (JP); Hiroaki Kawasaki, Nirasaki City (JP)

(73) Assignee: TOKYO ELECTRON LIMITED, Tokyo (JP)

(21) Appl. No.: 13/619,083

(22) Filed: Sep. 14, 2012

Related U.S. Application Data
(63) Continuation of application No. PCT/JP11/55674, filed on Mar. 10, 2011.

(30) Foreign Application Priority Data
Mar. 17, 2010 (JP) 2010-061629

(51) Int. Cl. H01L 21/768

(52) U.S. Cl. CPC H01L 21/76829
USPC 438/643

(57) ABSTRACT

A thin film forming method in which a thin film is formed on a surface of a target object to be processed to fill a recess formed in the surface of the target object includes the steps of forming a metal layer for filling on the surface of the target object to fill the recess formed in the surface of the target object and forming a metal film for preventing diffusion on an entire surface of the target object to cover the metal layer for filling. The thin film forming method further includes the step of annealing the target object having the metal film for preventing diffusion formed thereon.

This application is a Continuation Application of PCT International Application No. PCT/JP2011/055674 filed on Mar. 10, 2011, which designated the United States.

### FIELD OF THE INVENTION

The present invention relates to a thin film formation method used for filling a recess formed in a target object to be processed such as a semiconductor wafer or the like.

### BACKGROUND OF THE INVENTION

In general, a desired semiconductor device is manufactured by repeatedly performing various processes such as a film forming process, a pattern etching process and the like on a semiconductor wafer. Recently, due to a demand for high integration and high miniaturization of a semiconductor device, a line width or a hole diameter is getting finer. Although an aluminum alloy has been conventionally used as a wiring material or a filling material, tungsten W or copper Cu tends to be recently used in order to meet the demand for miniaturization of a line width or a hole diameter and increase of an operating speed.

When a metal material such as Al, W, Cu or the like is used as a wiring material or a filling material of a hole for contact, a barrier layer is formed at a boundary between the metal material and an insulating layer, e.g., a silicon oxide film (SiO₂) to prevent diffusion of silicon from the insulating material to the metal material or to improve adhesivity with the metal material. Further, the barrier layer is formed at a boundary between the metal material and an underlying conductive layer such as a wiring layer and an electrode to be contacted with the metal material at a bottom portion of the hole to improve adhesivity with the metal material. As for the barrier layer, a Ta film, a TaN film, a Ti film, a TiN film and the like are well known (see, e.g., Japanese Patent Application Publication Nos. 2003-142425, 2006-148074, 2004-335998, 2006-303062 and 2007-194624).

Recently, a thin liner layer is formed on the barrier layer in order to improve adhesivity with a filling metal. The liner layer is mainly made of a material having a lattice spacing that is close to that of the filling metal layer in order to improve adhesivity with the filling metal as described above. When the filled metal is Cu, for example, Ru (ruthenium) is mainly used as a material of the liner layer (see, e.g., JP2007-194624A).

JP2007-194624A specifically describes a method for forming a barrier film formed of, e.g., a TaN film, at a portion including an opening having a so-called Dual Damascene structure, forming a Ru film as a liner layer by CVD (Chemical Vapor Deposition), and then filling the opening with Cu.

As described above, since the Ru film serving as a liner layer is formed before Cu is filled, an adhesivity with Cu as the filling metal or the filling properties of Cu can be improved even if a line width of a hole diameter is miniaturized. However, when the Ru film is used as the liner layer, an electromigration resistance is decreased compared to when a Ta film, for example, is used as the liner layer.

In order to improve the electromigration resistance, JP2004-335998A suggests a method for forming a copper filling film, forming a copper metal wiring by removing an extra copper filling film except for a filled portion by chemical mechanical polishing, selectively laminating titanium or ruthenium on the copper metal wiring, and performing an annealing process. However, the film formation method described in JP2004-335998A is disadvantageous in that a grain size of a crystal grain of the copper film is comparatively small and electromigration resistance cannot be improved sufficiently in spite of the annealing process.

JP2006-303062A describes a method for filling a recess with a copper conductive film, forming a coating film made of titanium or ruthenium without removing an extra conductive film, and performing heat treatment. However, the purpose of JP2006-303062A is not to improve an electromigration resistance but to move crystal defects in the conductive film to the interface between the conductive film and the coating film and improve the crystal defects.

### SUMMARY OF THE INVENTION

In view of the above, the present invention provides a thin film forming method capable of improving adhesivity with a metal to be filled and filling characteristics and improving an electromigration resistance.

As a result of examination, the present inventors have conceived the present invention by discovering that when an annealing process is performed in a state where a metal film having a lattice spacing that is close to that of a material of a metal layer for filling is formed on a top surface of the metal layer for filling, grains in the metal layer for filling is effectively grown and, thus, an electromigration resistance can be improved.

In accordance with the present invention, there is provided a thin film forming method in which a thin film is formed on a surface of a target object to be processed to fill a recess formed in the surface of the target object, the method includes the steps of forming a metal layer for filling on the surface of the target object to fill the recess formed in the surface of the target object; forming a metal film for preventing diffusion on an entire surface of the target object to cover the metal layer for filling; and annealing the target object having the metal film for preventing diffusion formed thereon.

### BRIEF DESCRIPTION OF THE DRAWINGS

FIGS. 1A to 1H are cross sectional views showing a state of a semiconductor wafer as a target object to be processed in each process of a thin film forming method in accordance with an embodiment of the present invention.

FIG. 2 is a flowchart showing the thin film forming method in accordance with the embodiment of the present invention.

FIG. 3 shows a state of a crystal grain of each metal in comparison with Cu.

FIG. 4A is a schematic view showing a crystal lattice mismatch of Cu in the case of forming a liner layer formed of Ta or Ti and laminating a Cu layer thereon.

FIG. 4B is a schematic view showing a crystal lattice mismatch of Cu in the case of forming a liner layer formed of Ru and laminating a Cu layer thereon.

FIG. 5A is a cross sectional view showing a thin film laminated structure in which a metal film for preventing diffusion is not formed on a metal layer for filling, which is used for a test of examining effects of the metal film for preventing diffusion.

FIG. 5B a cross sectional view showing a thin film laminated structure in which a metal film for preventing diffusion is formed on a metal layer for filling, which is used for a test of examining effects of the metal film for preventing diffusion.

FIG. 6A schematically shows a crystal state of Cu which is obtained after forming a metal film for preventing diffusion and before performing an annealing process.

FIG. 6B schematically shows a crystal state of Cu which is obtained after forming a metal film for preventing diffusion and then performing an annealing process.

FIG. 7 is a graph showing a relationship among an annealing temperature, a grain size of a crystal grain of Cu, and a thickness of a Cu film.

FIG. 8 is a transmission type electron microscope image showing a cross section obtained by cutting a Cu film filled in a groove-shaped trench at a central portion of the trench.

FIG. 9 is a schematic view for explaining a cutting position of a specimen.

### DETAILED DESCRIPTION OF THE EMBODIMENTS

Hereinafter, an embodiment of the present invention will be described in detail with reference to the accompanying drawings which form a part hereof. Here, the case in which copper (Cu) is used for a metal layer for filling and ruthenium (Ru) is used for a liner layer will be described as an example.

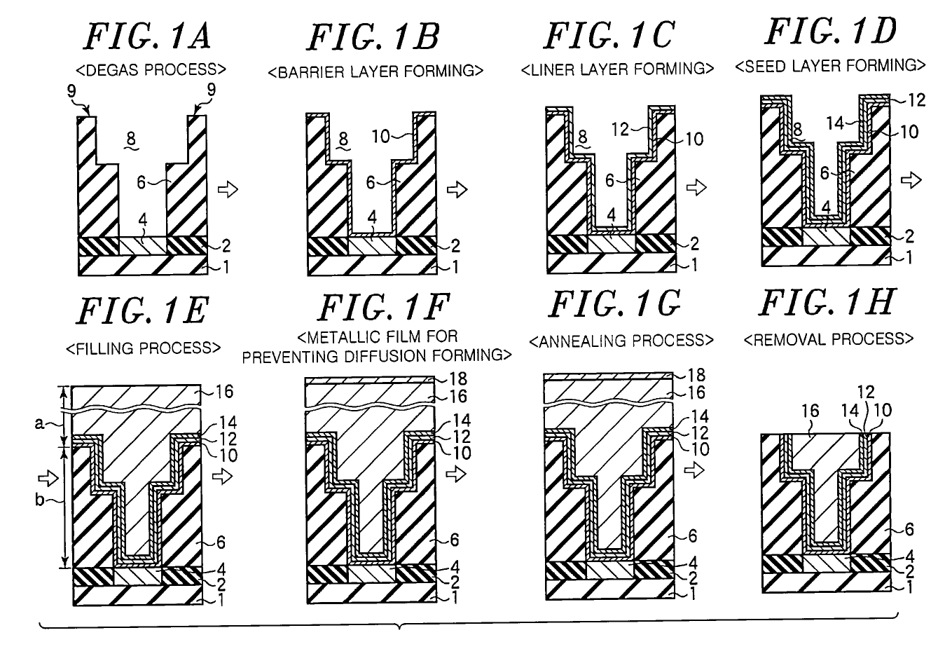

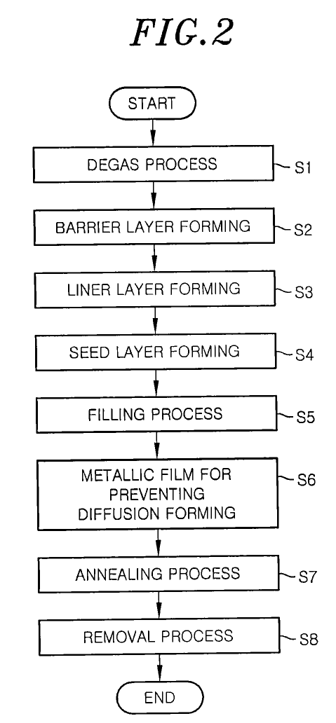

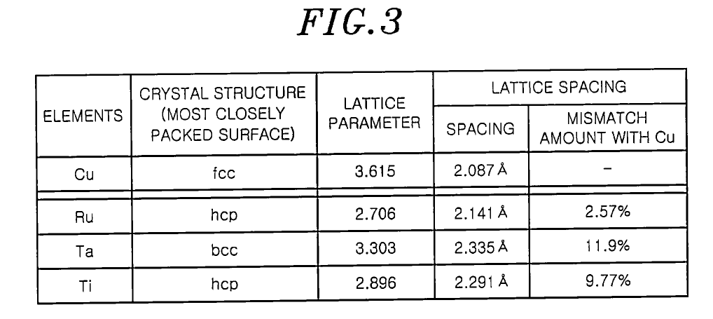

FIGS. 1A to 1H are cross sectional views showing a state of a semiconductor wafer as a target object to be processed in each process of a thin film forming method in accordance with an embodiment of the present invention. FIG. 2 is a flowchart showing the thin film forming method in accordance with the embodiment of the present invention.

Here, insulating layers 1 and 2 are sequentially formed on a surface of a silicon substrate shown in FIG. 1A which serves as a target object to be processed. Next, a conductive layer 4 formed of a wiring layer or the like is formed in the insulating layer 2. Thereafter, an insulating layer 6 formed of, e.g., a SiO₂ film or the like, which has a predetermined thickness is formed on an entire surface of the insulating layer 2 so as to cover the conductive layer 4. Then, a recess 8 for wiring and/or contact is formed in the insulating layer 6. The semiconductor wafer having the above-described structure is prepared, and a degas process is performed on the semiconductor wafer (S1). In the degas process, moisture or an organic material adhered to the surface of the semiconductor wafer is blown to be removed.

The conductive layer 4 of the semiconductor wafer may correspond to an electrode of a transistor or a capacitor. An etch stop layer formed on the interface between the insulating layer 2 and the insulating layer 6, or a barrier layer which covers a side surface or a bottom surface of the conductive layer 4 is not illustrated.

The recess 8 is formed of a via hole or a through hole for contact with the conductive layer 4 and/or a trench for wiring. Here, a so-called dual damascene structure having a cross section of a two-step structure in which a via hole for contact is formed at a bottom portion of a thin and long trench is shown. In this structure, the contact between a wiring to be formed at the trench and the underlying conductive layer 4 can be obtained by exposing the underlying conductive layer 4 to the bottom portion of the via hole.

In the semiconductor wafer having the above-described structure, a portion of the wafer surface excluding the recess 8 serves as a field portion 9. In other words, the field portion 9 indicates a flat portion on the top surface of the insulating layer 6 except for the recess 8 formed therein.

After the degas process is performed, as shown in FIG. 1B, a barrier layer 10 having a desired thickness is formed on an entire surface of the semiconductor wafer which includes a bottom surface and side surfaces of the recess 8, i.e., an entire upper surface of the insulating layer 6 (S2). The barrier layer 10 is formed in order to prevent diffusion of silicon from the insulating layer 6 to the filled metal or improve adhesivity of the filled metal to the insulating layer 6 and the conductive layer 4.

As for the barrier layer 10, various layers may be employed. For example, there may be used a two-story barrier layer in which a Ti film and a TiN film are sequentially laminated, a two-story barrier layer in which a TaN film and a Ta film are sequentially laminated, or a single barrier layer formed of any one of a Ti film, a TiN film, a Ta film and a TaN film. Besides, a single barrier layer formed of a W film or a two-story barrier layer in which a W film and a WN film are laminated may be used. The material and the structure of the barrier layer 10 are determined depending on types of a liner layer that is a conductive layer formed on top of the barrier layer 10. The barrier layer 10 has a thickness of, e.g., about 1 nm to 20 nm.

Next, as shown in FIG. 1C, a liner layer 12 is formed on the barrier layer 10 (S3). The liner layer 12 is used to improve filling properties and adhesivity with Cu used as a filling metal in a filling process to be performed later. In the present embodiment, Ru is used for the liner layer 12. However, it is also possible to use Co (cobalt), Ta (tantalum) or the like. However, Ru is preferably used to improve adhesivity and filling properties. The Ru film used as the liner layer 12 is preferably formed by a CVD method while using as a source material, e.g., Ru₃(CO)₁₂. In order to form the Ru film, a CVD film forming apparatus described in, e.g., Japanese Patent Application Publication No. 2010-037631, can be used. The liner layer 12 has a thickness of, e.g., about 1 nm to 10 nm.

Next, as shown in FIG. 1D, a seed layer 14 is formed on the liner layer 12 (S4). The seed layer 14 is used to improve efficiency of the filling process to be performed later. The seed layer 14 is made of a material that is basically the same as the filling metal. Here, Cu is used. The seed layer 14 can be formed by, e.g., a PVD (Physical Vapor Deposition) method, typically a sputtering method. The seed layer 14 has a thickness of, e.g., about 2 nm to 100 nm. The seed layer 14 may be omitted.

Next, as shown in FIG. 1E, a metal layer 16 for filling is formed by performing an filling process for filling the recess 8 with a filling metal (S5). Accordingly, the recess 8 is completely filled with the metal layer 16 for filling. As described above, Cu is used as the filling metal for forming the metal layer 16 for filling. This filling process can be performed mainly by a plating method. In addition, it is also possible to use a CVD method, an ALD (Atomic Layered Deposition) method for forming thin films by alternately supplying a source gas and a reactant gas, or a PVD method, i.e., a sputtering method.

In that case, it is preferable to form a thick metal layer 16 for filling such that a thickness “a” of the metal layer 16 for filling at a field portion 9 thereof corresponding to a surface of the wafer W excluding the recess 8 becomes greater than a depth “b” of the recess 8. In other words, the metal layer 16 for filling is formed until “a≧b” is satisfied. Accordingly, as will be described later, it is possible to increase a grain size of a crystal grain of Cu forming the metal layer 16 for filling which grows in an annealing process to be performed later.

Next, as shown in FIG. 1F, a diffusion prevention film forming process for forming the metal film 18 for preventing diffusion which is the characteristic of the method of the present invention on the entire surface of the semiconductor wafer so as to cover the entire top surface of the metal layer 16 for filling (S6). The metal film 18 for preventing diffusion is made of a metal material having a lattice spacing that is close to that of a metal material of the metal layer 16 for filling. Here, Cu is used for the metal layer 16 for filling, so that Ru is used for the metal material having a lattice spacing that is close to that of Cu. The Ru film forming method is the same as the method for forming the liner layer 12 formed of a Ru film which is described in FIG. 1C.

By forming the metal film 18 for preventing diffusion, the diffusion of atoms on the surface of the metal layer 16 for filling can be suppressed in the annealing process to be performed later. Therefore, the energy which may be consumed by the diffusion can be utilized for growth of grains in the metal film. As a result, the growth of grains (crystal grains) can be effectively facilitated.

In that case, the thickness of the metal film 18 for preventing diffusion is preferably about 0.5 nm or above. If the thickness thereof is smaller than about 0.5 nm, the metal film 18 for preventing diffusion cannot be uniformly formed on the top surface of the metal layer 16 for filling. Accordingly, the film formation becomes non-uniform and, thus, the above-described effect may not be effectively obtained. Further, if the thickness of the metal film 18 for preventing diffusion is excessively increased, a removal process to be described later requires a long period of time, which results in a decrease of a throughput. Therefore, the film thickness is preferably about 50 nm or below.

Next, as shown in FIG. 1G, the semiconductor wafer having the metal film 18 for preventing diffusion thereon is subjected to an annealing process while being exposed to a high temperature state, and a crystal structure of each metal atom is stabilized (S7). The annealing temperature is preferably in the range of about 100° C. to 500° C., more preferably in the range of about 150° C. to 400° C., and most preferably in the range of about 200° C. to 350° C. When the annealing temperature is lower than about 100° C., the effect of the annealing is not sufficiently obtained. On the other hand, when the annealing temperature is excessively higher than about 500° C., a phenomenon in which atoms are pulled upward occurs, which is not preferable.

By forming the metal film 18 for preventing diffusion made of Ru on the surface of the metal layer 16 for filling made of Cu, the adhesivity therebetween is increased because lattice spacings thereof are very close to each other. When the annealing process of the step S7 is performed, thermal diffusion of Cu atoms on the Cu surface is suppressed. Hence, energy which may be consumed by the thermal diffusion is utilized for growth of grains, and the growth of crystal grains, i.e., grains, is effectively facilitated. As a result, a length or an area of an interface between crystal grains where electromigration tends to occur is decreased, and the occurrence of electromigration is suppressed by the corresponding amount.

Next, as shown in FIG. 1H, a removal process for removing the residual thin film on the surface of the semiconductor wafer is performed (S8). In this removal process, an unnecessary thin film remaining at the outer side of the recess 8 or on the surface of the semiconductor wafer is removed by, e.g., a CMP (Chemical Mechanical Polishing) process. Accordingly, the filling the recess is completed.

In the present embodiment, the metal layer 16 for filling is formed on the surface of the semiconductor wafer as a target object to be processed having the recess 8 thereon so as to fill the recess 8 and, then, the metal film 18 for preventing diffusion is formed on the entire surface of the semiconductor wafer as a target object to be processed so as to cover the metal layer 16 for filling. Next, the semiconductor wafer as a target object to be processed is annealed. Accordingly, the filling properties and adhesivity of the filled metal can be improved, and the electromigration resistance can be improved.

### Evaluation of the Method of the Present Invention

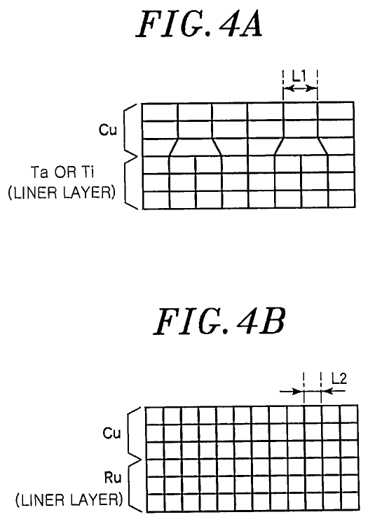

Next, an evaluation result obtained by testing the thin film formation method of the present invention will be explained. First, the effect of the liner layer 12 will be described before explanation of the effect of the metal film 18 for preventing diffusion. As described above, the liner layer 12 is formed in order to improve adhesivity to a Cu film as the metal layer 16 for filling. In order to improve the adhesivity, the liner layer 12 is preferably made of a material having a lattice spacing that is close to that of Cu. FIG. 3 shows a state of a crystal structure of each metal in comparison with Cu. FIGS. 4A and 4B are schematic views showing states of spacing in the case of forming a Cu layer on a liner layer.

FIG. 3 shows a crystal structure of the most closely packed surface, a lattice parameter, a lattice spacing (spacing and mismatch with Cu) of each of Cu, Ru, Ta, and Ti. Especially, according to the spacing and the mismatch with Cu in the lattice spacing, a spacing of Ru is closest to that of the Cu(111) surface. Crystal lattice mismatches of Ta and Ti are about 11.95 and 9.77%, respectively. On the other hand, a mismatch of a crystal lattice of Ru is about 2.57%, which is smallest.

Hence, by using a Ru metal for the liner layer 12, the adhesivity to the Cu film can be improved, and the filling properties of the recess can be improved. FIGS. 4A and 4B show mismatches of crystal lattices of Cu. FIG. 4A shows the case in which Ta or Ti is used for the liner layer. FIG. 4B shows the case in which Ru is used for the liner layer.

As shown in FIG. 4A, when Ta or Ti having a large mismatch of spacing is used for an underlying liner layer, a lattice spacing L1 of a Cu film formed thereon becomes considerably different from an original lattice spacing. Therefore, distortion occurs and adhesivity therebetween is decreased.

On the other hand, as shown in FIG. 4B, when Ru having a small mismatch of spacing is used for an underlying liner layer, a lattice spacing L2 of the Cu film formed thereon becomes close to the original lattice spacing. As a result, the adhesivity therebetween can be considerably improved.

According to the comparison of the grain sizes of the Cu films, even if the annealing process is performed, the Cu crystal hardly grows due to the good adhesivity at the Cu/Ru interface. As a result, the grain size of the Cu film formed on the Ru film becomes smaller than that of the Cu film formed on the Ti film or the Ti film. For example, when the annealing process was performed on the Cu film formed on a laminated structure of the TaN film having a thickness of about 4 nm and the Ta film having a thickness of about 2 nm, the crystal size of the Cu(111) surface was about 15 nm. On the other hand, when the annealing process was performed on the Cu film formed on a laminated structure of the Ru films, the crystal size of the Cu(111) surface was about 11 nm. This shows that when a Ru layer is used for a liner layer, the adhesivity is improved but the crystal size of the Cu film is decreased.

Here, the electromigration tends to occur by grain boundary diffusion at the crystal (grain) interface in the Cu film. Therefore, as described above, when the crystal size of the Cu film is decreased, a length or an area of the interface between Cu crystals is increased by the corresponding amount. Hence, the grain boundary diffusion easily occurs, and the electromigration resistance is decreased. Further, the decreased crystal size of the Cu film may lead to formation of a void in the Cu film when the Cu crystal grows in a next process.

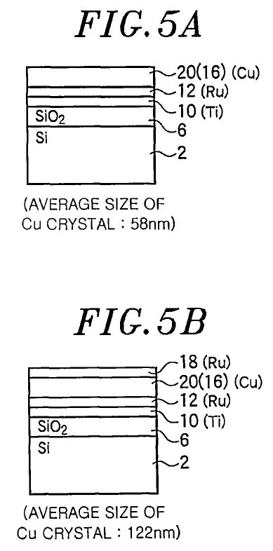

Thus, in the present invention, the metal film 18 for preventing diffusion is formed on the Cu film as the metal layer 16 for filling to thereby facilitate the crystal growth while suppressing diffusion on the Cu film surface, as described above. In order to examine the effect of the metal film 18 for preventing diffusion, there were prepared a semiconductor wafer on which a metal film for preventing diffusion is formed as shown in FIG. 5A and a semiconductor wafer on which a metal film for preventing diffusion is not formed as shown in FIG. 5B and, then, the Cu crystal growth was observed.

FIGS. 5A and 5B show cross sectional views of a laminated structure of thin films in the case of performing a test for examining an effect of the metal film for preventing diffusion. FIG. 5A shows a specimen in which the metal film 18 for preventing diffusion is not formed on the metal layer 16 for filling. FIG. 5B shows a specimen in which the metal film 18 for preventing diffusion is formed on the metal layer 16 for filling.

FIG. 5A shows the conventional method in which an insulating layer 6 formed of a SiO₂ film, a barrier layer 10 formed of a Ti film, a liner layer 12 formed of a Ru film, and a Cu film 20 corresponding to the metal layer 16 for filling are sequentially laminated on a semiconductor wafer as a silicon substrate.

Meanwhile, FIG. 5B shows the method of the present invention in which an insulating layer 6 formed of a SiO₂ film, a barrier layer 10 formed of a Ti film, a liner layer 12 formed of a Ru film, a Cu film 20 corresponding to a metal layer 16 for filling, and a metal film 18 for preventing diffusion formed of a Ru film are sequentially laminated on a silicon substrate.

Each of the specimens having thereon various thin films shown in FIGS. 5A and 5B was subjected to an annealing process at about 150° C. for 30 minutes. Then, a size of a Cu crystal in each Cu film 20 was measured. As a result, it was found that when the conventional method shown in FIG. 5A was used, the average size of the Cu crystal in the Cu film 20 was about 58 nm. On the other hand, when the method of the present invention shown in FIG. 5B was used, the average size of the Cu crystal in the Cu film 20 was about 122 nm. In other words, an approximately double-sized Cu crystal was obtained.

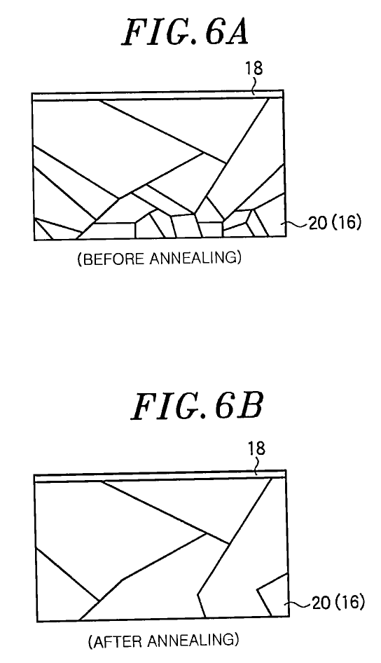

FIGS. 6A and. 6B schematically show the state of the Cu crystal in the Cu film of the specimen corresponding to the method of the present invention of FIG. 5B. FIG. 6 shows the state before an annealing process, and FIG. 6B shows the state after an annealing process. Before the annealing process, the Cu crystal size in the Cu film 20 is considerably small as shown in FIG. 6A. After the annealing process, the Cu crystal is grown to a large size as shown in FIG. 6B.

The reason that the growth of crystal is facilitated by performing an annealing process in a state where the metal film 18 for preventing diffusion is formed on the surface of the Cu film 20 corresponding to the metal layer 16 for filling is considered as follows. In other words, since the energy is highest on the surface of the Cu film, atoms on the surface are easily moved and thermally diffused. However, when a Ru film having a small mismatch of lattice spacing is formed on the surface of the Cu film, they are strongly bonded at the interface therebetween and, thus, the thermal diffusion is suppressed. Hence, the energy which may be consumed by the thermal diffusion, is utilized for the growth of Cu crystal, and the Cu crystal grows in the Cu film as described above. Therefore, in accordance with the present invention, the adhesivity of the filled metal and the filling properties can be improved, and the electromigration resistance caused by the Cu grain boundary diffusion can be improved.

As described above, when the metal layer 16 for filling is formed, the metal layer 16 for filling in the field portion 9 is formed with a thickness a greater than or equal to a depth b of the recess 8 (a≧b). Accordingly, a crystal grain of Cu forming the metal layer 16 for filling can be remarkably grown in the annealing process. In other words, the Cu crystal grain grows from the upper portion to the lower portion of the Cu film, so that the crystal grain growth is facilitated by forming a large amount of a thick Cu film on the field portion 9 such that “a≧b” is satisfied, and sufficiently large crystal grains grow to the bottom portion of the Cu film. Thus, in order to allow the sufficiently large crystal grains to grow to the Cu film (the metal layer 16 for filling) deposited on the bottom portion of the recess 8, it is preferable to set the thickness a of the metal layer 16 for filling in the field portion 9 to be greater than or equal to the depth b of the recess 8 as described above.

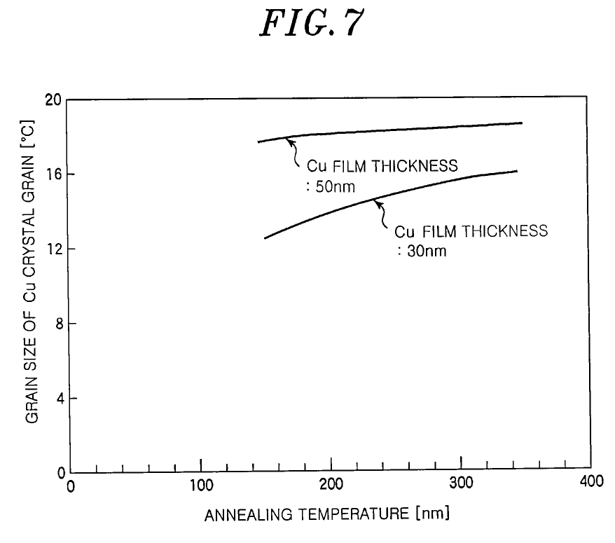

As described above, as the thickness of the Cu film as the metal layer 16 for filling is increased, a grain size of a crystal grain of the Cu film can be increased in the annealing process. FIG. 7 is a graph showing a relationship among an annealing temperature, a Cu film thickness and a grain size of a Cu crystal grain. Here, two specimens were obtained by forming a SiO₂ film, a TaN film (4 nm), a Ru film (2 nm) and a Cu film as a metal layer for filling in that order on a wafer as a silicon substrate and then forming a Ru film as a metal film for preventing diffusion on the surface thereof. The specimens were subjected to an annealing process (pressure: about 10 Torr, 30 min). One specimen had a Cu film of about 30 nm, and the other specimen had a Cu film of about 50 nm. The annealing process was performed on the two specimens. A grain size of a crystal grain was measured by using a XRD (fluorescent X-ray analyzer).

As clearly can be seen from this graph, when a thickness of a Cu film as the metal layer for filling is increased from about 30 nm to 50 nm, the grain size of the Cu crystal grain which depends on the annealing temperature is increased from the range of about 13 nm to 16 nm to the range of about 18 nm to 19 nm. In other words, as the thickness of the Cu film is increased, the grain size of the crystal grain can be increased.

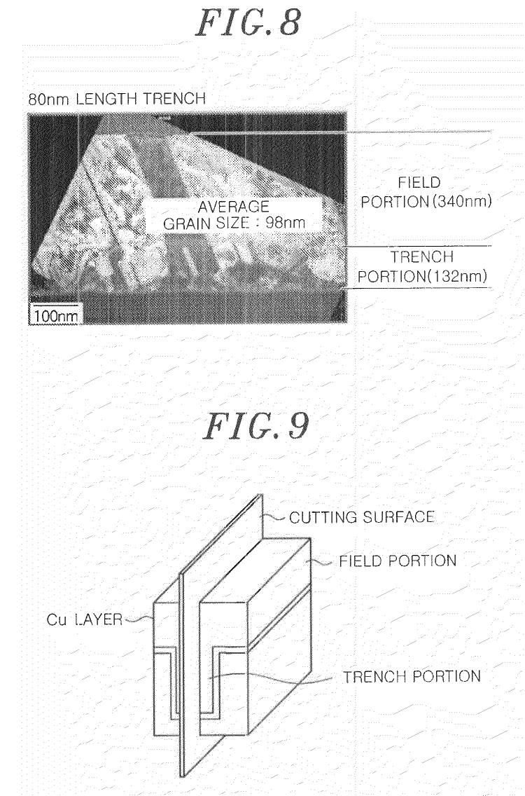

A Cu film fills the recess 8 formed of a groove-shaped trench portion having a depth “b” of about 132 nm and a width of about 80 nm by using the above-described film forming method, and the Cu film is formed at the field portion having a thickness of about 340 nm. A grain size of a Cu crystal grain after an annealing process was measured by a transmission electron microscope (TEM). The result thereof is shown in FIG. 8. FIG. 8 is a TEM image showing a cross section obtained by cutting a central portion of the groove-shaped trench portion as the recess in which the Cu film is filled. Here, as shown in FIG. 9, the cross section is obtained by cutting the central portion of the trench portion in a vertical direction. An average grain size of a Cu crystal grain in FIG. 8 is about 98 nm, and a grain size greater than the trench width of about 80 nm is obtained.

In that case, a grain size of a Cu crystal grain is preferably greater than or equal to a width of the recess 8 as a trench portion, i.e., a width of the wiring. Actually, the grain size is preferably set in the range of about 1 to 2 times a width (opening width) of the recess 8. In a current semiconductor integrated circuit, a width of a recess, i.e., a width of a trench, is about 10 nm to 200 nm. A depth of the recess as a trench portion is about 100 nm to 250 nm, and a ratio between the width of the trench and the depth of the trench, i.e., an aspect ratio AR, is about 2 to 10.

The present invention can be variously modified without being limited to the above-described embodiment. For example, the above-described embodiment has described the case in which Cu is used for the metal layer 16 for filling. However, W or Al may also be used other than Cu. In other words, the metal layer 16 for filling can be made of a material selected from the group consisting of Cu, W and Al.

In the above-described embodiment, the case in which Ru is used for the metal film 18 for preventing diffusion has been described. However, any metal can be used for the metal film 18 for preventing diffusion for preventing diffusion, as long as it pushes the metal layer 16 for filling from above to prevent diffusion of atoms on the surface. In addition, Co, Ta or Ti may be preferably used for the metal film 18 for preventing diffusion. In other words, the metal film for preventing diffusion can be made of a material selected from the group consisting of Ru, Co, Ta and Ti.

In the above-describe embodiment, a semiconductor wafer is described as an example of the target object to be processed. However, the semiconductor wafer includes a silicon substrate, a compound semiconductor substrate such as GaAs, SiC, GaN or the like. The present invention can be applied to a glass substrate for a liquid crystal display, a ceramic substrate or the like without limited to the above substrates.

What is claimed is:

1. A thin film forming method in which a thin film is formed on a surface of a target object to be processed to fill a recess formed in the surface of the target object, the method comprising the steps of:
forming a metal layer for filling on the surface of the target object to fill the recess formed in the surface of the target object;
forming a metal film for preventing diffusion on an entire surface of the target object to cover the metal layer for filling; and
annealing the target object having the metal film for preventing diffusion formed thereon.

2. The thin film forming method of claim 1, wherein, when forming the metal layer for filling to fill the recess, a thickness of the metal layer for filling in a field portion corresponding to a portion of the surface of the target object except for the recess is greater than or equal to a depth of the recess.

3. The thin film forming method of claim 1, wherein in the step of annealing the target object, a grain diameter of a crystal grain of the metal layer for filling becomes greater than or equal to a width of the recess.

4. The thin film forming method of claim 1, further comprising, before the step of forming the metal layer for filling to fill the recess, a step of forming a barrier layer.

5. The thin film forming method of claim 4, further comprising, between the step of forming the barrier film and the step of forming the metal layer for filling to fill the recess, a step of forming a seed layer.

6. The thin film forming method of claim 1, further comprising, before the step of forming the metal layer for filling to fill the recess, a step of forming a barrier layer and a step of forming a liner layer on the barrier layer.

7. The thin film forming method of claim 6, further comprising, between the step of forming the liner layer and the step of forming the metal layer for filling to fill the recess, a step of forming a seed layer.

8. The thin film forming method of claim 1, wherein the step of annealing the target object is performed at a temperature ranging 100° C. to 500° C.

9. The thin film forming method of claim 1, further comprising, after forming the metal film for preventing diffusion, a step of removing the metal film for preventing diffusion and the metal layer for filling except for a portion filled in the recess.

10. The thin film forming method of claim 1, wherein the metal layer for filling is made of a material selected from the group consisting of Cu, W, and Al.

11. The thin film forming method of claim 1, wherein the metal film for preventing diffusion is made of a material selected from the group consisting of Ru, Co, Ta, and Ti.

12. The thin film forming method of claim 1, wherein the metal layer for filling is formed by a method selected from the group consisting of a CVD (Chemical Vapor Deposition) method, an ALD (Atomic Layered Deposition) method, a PVD (Physical Vapor Deposition) method, and a plating method.

13. The thin film forming method of claim 1, wherein the metal film for preventing diffusion is formed by a method selected from the group consisting of a CVD (Chemical Vapor Deposition) method, an ALD (Atomic Layered Deposition) method, a PVD(Physical Vapor Deposition) method, and a plating method.

14. The thin film forming method of claim 1, wherein the metal film for preventing diffusion has a thickness in a range 0.5 nm to 50 nm.

15. The thin film forming method of claim 6, wherein the liner layer is made of Ru.

16. The thin film forming method of claim 11, wherein the metal film for preventing diffusion is made of Ru.
